(19) United States
(12) Patent Application Publication
(10) Pub. No.: US 2023/0217735 A1
(43) Pub. Date: Jul. 6, 2023

(54) DISPLAY DEVICE

(71) Applicant: Japan Display Inc., Tokyo (JP)

(72) Inventor: Hiroshi TABATAKE, Tokyo (JP)

(73) Assignee: Japan Display Inc., Tokyo (JP)

(21) Appl. No.: 18/086,662

(22) Filed: Dec. 22, 2022

(30) Foreign Application Priority Data
Jan. 6, 2022 (JP) 2022-001085

(51) Int. Cl. H10K 59/124; H10K 59/123

(52) U.S. Cl. CPC H10K 59/124; H10K 59/123; H10K 2102/302

(57) ABSTRACT

According to one embodiment, a display device includes a substrate, a pixel circuit, an insulating layer including a contact hole, a lower electrode connected to the pixel circuit through the contact hole, an upper electrode, an organic layer between the lower and upper electrodes, a rib including an aperture, a partition above the rib, and a filling material inside the contact hole. The organic layer includes a first organic layer in contact with the lower electrode through the aperture, and a second organic layer on the partition. The partition and the rib overlap at least part of the contact hole and the filling material in plan view.

### CROSS-REFERENCE TO RELATED APPLICATIONS

This application is based upon and claims the benefit of priority from Japanese Patent Application No. 2022-001085, filed Jan. 6, 2022, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer.

In general, the pixel circuit is covered with an insulating layer formed of an organic material. The lower electrode is connected to the pixel circuit through a contact hole provided in the insulating layer. When the element provided on the insulating layer is deformed by the contact hole, there is a possibility that a display failure occurs.

### BRIEF DESCRIPTION OF THE DRAWINGS

FIG. 1 is a diagram showing a configuration example of a display device according to a first embodiment.

FIG. 2 is a diagram showing an example of the layout of subpixels according to the first embodiment.

FIG. 3 is a schematic cross-sectional view of the display device along the III-III line of FIG. 2.

FIG. 4 is a schematic plan view in which part of FIG. 2 is enlarged.

FIG. 5 is a schematic cross-sectional view of the display device along the V-V line of FIG. 4.

FIG. 6 is a schematic cross-sectional view showing part of the manufacturing process of the display device according to the first embodiment.

FIG. 7 is a schematic cross-sectional view of a display device according to a comparative example.

FIG. 8 is a schematic cross-sectional view of a display device according to a second embodiment.

FIG. 9 is a schematic cross-sectional view of a display device according to a third embodiment.

FIG. 10 is a schematic cross-sectional view of a display device according to a fourth embodiment.

### DETAILED DESCRIPTION

In general, according to one embodiment, a display device comprises a substrate, a pixel circuit provided above the substrate, an insulating layer which covers the pixel circuit and comprises a contact hole, a lower electrode provided above the insulating layer and connected to the pixel circuit through the contact hole, an upper electrode facing the lower electrode, an organic layer which is located between the lower electrode and the upper electrode and emits light based on a potential difference between the lower electrode and the upper electrode, a rib formed of an inorganic material and comprising an aperture overlapping the lower electrode, a partition provided above the rib, and a filling material provided inside the contact hole. The organic layer includes a first organic layer which is in contact with the lower electrode through the aperture, and a second organic layer located on the partition and spaced apart from the first organic layer. The partition and the rib overlap at least part of the contact hole and the filling material as seen in plan view.

This configuration can provide a display device which can improve the display quality.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated in the drawings schematically, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction. A direction parallel to the Y-axis is referred to as a second direction. A direction parallel to the Z-axis is referred to as a third direction. A plan view is defined as appearance when various types of elements are viewed parallel to the third direction Z.

The display device of each embodiment is an organic electroluminescent display device comprising an organic light emitting diode (OLED) as a display element, and could be mounted on a television, a personal computer, a vehicle-mounted device, a tablet, a smartphone, a mobile phone, etc.

### [First Embodiment]

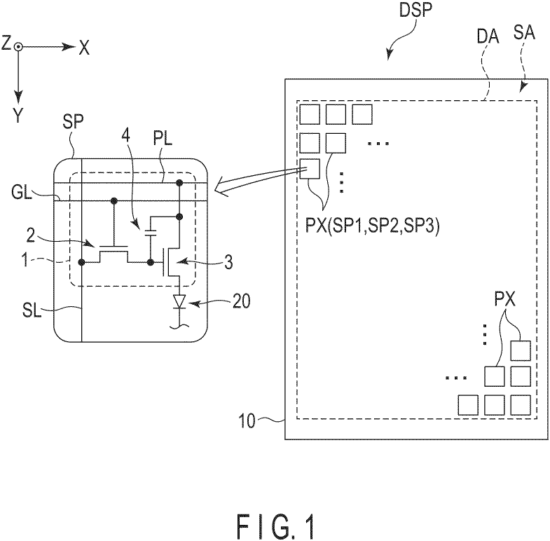

FIG. 1 is a diagram showing a configuration example of a display device DSP according to a first embodiment. The display device DSP comprises a display area DA which displays an image and a surrounding area SA around the display area DA on an insulating substrate 10. The substrate 10 may be glass or a resinous film having flexibility.

In the present embodiment, the substrate 10 is rectangular as seen in plan view. It should be noted that the shape of the substrate 10 in a plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes a red subpixel (first subpixel) SP1, a green subpixel (second subpixel) SP2 and a blue subpixel (third subpixel) SP3. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element. For example, subpixel SP1 comprises a display element 20 which emits light in a red wavelength range. Subpixel SP2 comprises a display element 20 which emits light in a green wavelength range. Subpixel SP3 comprises a display element 20 which emits light in a blue wavelength range.

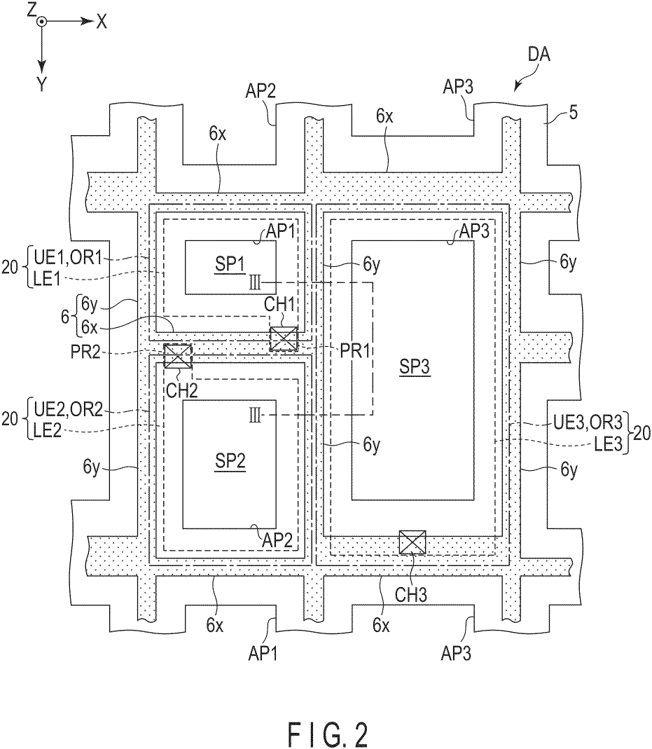

FIG. 2 is a diagram showing an example of the layout of subpixels SP1, SP2 and SP3. In the example of FIG. 2, subpixels SP1 and SP2 are arranged in the second direction Y. Further, each of subpixels SP1 and SP2 is adjacent to subpixel SP3 in the first direction X.

When subpixels SP1, SP2 and SP3 are provided in line with this layout, in the display area DA, a column in which subpixels SP1 and SP2 are alternately provided in the second direction Y and a column in which a plurality of subpixels SP3 are repeatedly provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

A rib 5 and a partition 6 are provided in the display area DA. The rib 5 comprises apertures AP1, AP2 and AP3 in subpixels SP1, SP2 and SP3, respectively. In the example of FIG. 2, the aperture AP2 is larger than the aperture AP1, and the aperture AP3 is larger than the aperture AP2.

The partition 6 overlaps the rib 5 as seen in plan view. The partition 6 comprises a plurality of first partitions 6x extending in the first direction X and a plurality of second partitions 6y extending in the second direction Y. The first partitions 6x are provided between the apertures AP1 and AP2 which are adjacent to each other in the second direction Y and between two apertures AP3 which are adjacent to each other in the second direction Y. Each second partition 6y is provided between the apertures AP1 and AP3 which are adjacent to each other in the first direction X and between the apertures AP2 and AP3 which are adjacent to each other in the first direction X.

In the example of FIG. 2, the first partitions 6x and the second partitions 6y are connected to each other. In this configuration, the partition 6 has a grating shape surrounding the apertures AP1, AP2 and AP3 as a whole. In other words, the partition 6 comprises apertures in subpixels SP1, SP2 and SP3 in a manner similar to that of the rib 5.

Subpixel SP1 comprises a lower electrode LE1, an upper electrode UE1 and an organic layer OR1 overlapping the aperture AP1. Subpixel SP2 comprises a lower electrode LE2, an upper electrode UE2 and an organic layer OR2 overlapping the aperture AP2. Subpixel SP3 comprises a lower electrode LE3, an upper electrode UE3 and an organic layer OR3 overlapping the aperture AP3. In the example of FIG. 2, the outer shapes of the upper electrode UE1 and the organic layer OR1 are coincident with each other. The outer shapes of the upper electrode UE2 and the organic layer OR2 are coincident with each other. The outer shapes of the upper electrode UE3 and the organic layer OR3 are coincident with each other.

The lower electrode LE1, the upper electrode UE1 and the organic layer OR1 constitute the display element 20 of subpixel SP1. The lower electrode LE2, the upper electrode UE2 and the organic layer OR2 constitute the display element 20 of subpixel SP2. The lower electrode LE3, the upper electrode UE3 and the organic layer OR3 constitute the display element 20 of subpixel SP3.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

The contact holes CH1, CH2 and CH3 overlap the rib 5 as a whole. At least part of the contact holes CH1 and CH2 overlaps the first partition 6x between the apertures AP1 and AP2 which are adjacent to each other in the second direction Y. At least part of the contact hole CH3 overlaps the first partition 6x between two apertures AP3 which are adjacent to each other in the second direction Y.

In the example of FIG. 2, the lower electrode LE1 comprises a protrusion PR1 which protrudes toward the lower electrode LE2, and the lower electrode LE2 comprises a protrusion PR2 which protrudes toward the lower electrode LE1. The contact holes CH1 and CH2 overlap the protrusions PR1 and PR2, respectively.

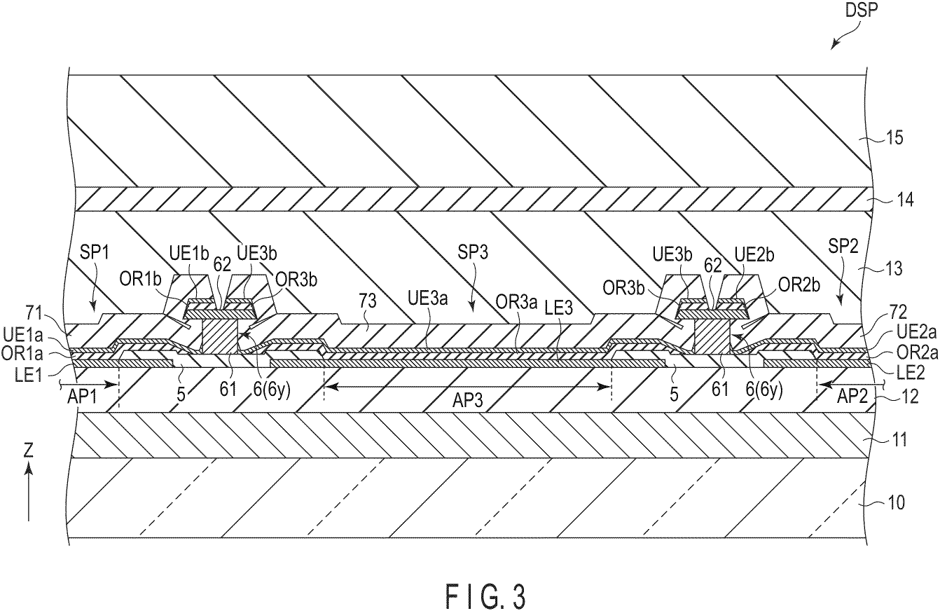

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, scanning line GL, signal line SL and power line PL shown in FIG. 1. The circuit layer 11 is covered with an insulating layer 12. The insulating layer 12 functions as a planarization film which planarizes the irregularities generated by the circuit layer 11. Although not shown in the section of FIG. 3, the contact holes CH1, CH2 and CH3 described above are provided in the insulating layer 12.

The lower electrodes LE1, LE2 and LE3 are provided on the insulating layer 12. The rib 5 is provided on the insulating layer 12 and the lower electrodes LE1, LE2 and LE3. The end portions of the lower electrodes LE1, LE2 and LE3 are covered with the rib 5.

The partition 6 includes a lower portion 61 provided on the rib 5 and an upper portion 62 which covers the upper surface of the lower portion 61. The upper portion 62 has a width greater than that of the lower portion 61. By this configuration, in FIG. 3, the both end portions of the upper portion 62 protrude relative to the side surfaces of the lower portion 61. This shape of the partition 6 may be also called an overhang shape.

The organic layer OR1 shown in FIG. 2 includes first and second organic layers OR1a and OR1b spaced apart from each other. The upper electrode UE1 shown in FIG. 2 includes first and second upper electrodes UE1a and UE1b spaced apart from each other. As shown in FIG. 3, the first organic layer OR1a is in contact with the lower electrode LE1 through the aperture AP1 and covers part of the rib 5. The second organic layer OR1b is located on the upper portion 62. The first upper electrode UE1a faces the lower electrode LE1 and covers the first organic layer OR1a. Further, the first upper electrode UE1a is in contact with a side surface of the lower portion 61. The second upper electrode UE1b is located above the partition 6 and covers the second organic layer OR1b.

The organic layer OR2 shown in FIG. 2 includes first and second organic layers OR2a and OR2b spaced apart from each other. The upper electrode UE2 shown in FIG. 2 includes first and second upper electrodes UE2a and UE2b spaced apart from each other. As shown in FIG. 3, the first organic layer OR2a is in contact with the lower electrode LE2 through the aperture AP2 and covers part of the rib 5. The second organic layer OR2b is located on the upper portion 62. The first upper electrode UE2a faces the lower electrode LE2 and covers the first organic layer OR2a. Further, the first upper electrode UE2a is in contact with a side surface of the lower portion 61. The second upper electrode UE2b is located above the partition 6 and covers the second organic layer OR2b.

The organic layer OR3 shown in FIG. 2 includes first and second organic layers OR3a and OR3b spaced apart from each other. The upper electrode UE3 shown in FIG. 2 includes first and second upper electrodes UE3a and UE3b spaced apart from each other. As shown in FIG. 3, the first organic layer OR3a is in contact with the lower electrode LE3 through the aperture AP3 and covers part of the rib 5. The second organic layer OR3b is located on the upper portion 62. The first upper electrode UE3a faces the lower electrode LE3 and covers the first organic layer OR3a. Further, the first upper electrode UE3a is in contact with a side surface of the lower portion 61. The second upper electrode UE3b is located above the partition 6 and covers the second organic layer OR3b.

Sealing layers 71, 72 and 73 are provided in subpixels SP1, SP2 and SP3, respectively. The sealing layer 71 continuously covers the first upper electrode UE1a, the side surface of the lower portion 61 and the second upper electrode UE1b. The sealing layer 72 continuously covers the first upper electrode UE2a, the side surface of the lower portion 61 and the second upper electrode UE2b. The sealing layer 73 continuously covers the first upper electrode UE3a, the side surface of the lower portion 61 and the second upper electrode UE3b.

In the example of FIG. 3, the second organic layer OR1b, the second upper electrode UE1b and the sealing layer 71 on the partition 6 between subpixels SP1 and SP3 are spaced apart from the second organic layer OR3b, the second upper electrode UE3b and the sealing layer 73 on this partition 6. In addition, the second organic layer OR2b, the second upper electrode UE2b and the sealing layer 72 on the partition 6 between subpixels SP2 and SP3 are spaced apart from the second organic layer OR3b, the second upper electrode UE3b and the sealing layer 73 on this partition 6.

The sealing layers 71, 72 and 73 are covered with a resinous layer 13. The resinous layer 13 is covered with a sealing layer 14. Further, the sealing layer 14 is covered with a resinous layer 15.

The insulating layer 12 and the resinous layers 13 and 15 are formed of an organic material. The rib 5 and the sealing layers 14, 71, 72 and 73 are formed of, for example, an inorganic material such as silicon nitride (SiNx). The thickness of the rib 5 formed of an inorganic material is sufficiently less than that of the partition 6 and the insulating layer 12. For example, the thickness of the rib 5 is greater than or equal to 200 nm and less than or equal to 400 nm.

The lower portion 61 of the partition 6 is conductive. The upper portion 62 of the partition 6 may be also conductive. The lower electrodes LE1, LE2 and LE3 may be formed of a transparent conductive material such as ITO or may comprise a multilayer structure of a metal material such as silver (Ag) and a transparent conductive material. The upper electrodes UE1, UE2 and UE3 are formed of, for example, a metal material such as an alloy of magnesium and silver (MgAg). The upper electrodes UE1, UE2 and UE3 may be formed of a transparent conductive material such as ITO.

When the potential of the lower electrodes LE1, LE2 and LE3 is relatively higher than that of the upper electrodes UE1, UE2 and UE3, the lower electrodes LE1, LE2 and LE3 are equivalent to anodes, and the upper electrodes UE1, UE2 and UE3 are equivalent to cathodes. When the potential of the upper electrodes UE1, UE2 and UE3 is relatively higher than that of the lower electrodes LE1, LE2 and LE3, the upper electrodes UE1, UE2 and UE3 are equivalent to anodes, and the lower electrodes LE1, LE2 and LE3 are equivalent to cathodes.

The organic layers OR1, OR2 and OR3 include a pair of function layers and a light emitting layer provided between these function layers. For example, the organic layers OR1, OR2 and OR3 comprise a structure in which a hole injection layer, a hole transport layer, an electron blocking layer, a light emitting layer, a hole blocking layer, an electron transport layer and an electron injection layer are stacked in order.

Subpixels SP1, SP2 and SP3 may further include a cap layer for adjusting the optical property of the light emitted from the respective light emitting layers of the organic layers OR1, OR2 and OR3. These cap layers may be provided between the upper electrode UE1 and the sealing layer 71, between the upper electrode UE2 and the sealing layer 72 and between the upper electrode UE3 and the sealing layer 73, respectively.

Common voltage is applied to the partition 6. This common voltage is applied to each of the first upper electrodes UE1a, UE2a and UE3a which are in contact with side surfaces of the lower portions 61. Pixel voltage is applied to the lower electrodes LE1, LE2 and LE3 through the pixel circuits 1 provided in subpixels SP1, SP2 and SP3, respectively.

When a potential difference is formed between the lower electrode LE1 and the upper electrode UE1, the light emitting layer of the first organic layer OR1a emits light in a red wavelength range. When a potential difference is formed between the lower electrode LE2 and the upper electrode UE2, the light emitting layer of the first organic layer OR2a emits light in a green wavelength range. When a potential difference is formed between the lower electrode LE3 and the upper electrode UE3, the light emitting layer of the first organic layer OR3a emits light in a blue wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including a quantum dot which generates light exhibiting colors corresponding to subpixels SP1, SP2 and SP3 by the excitation caused by the light emitted from the light emitting layers.

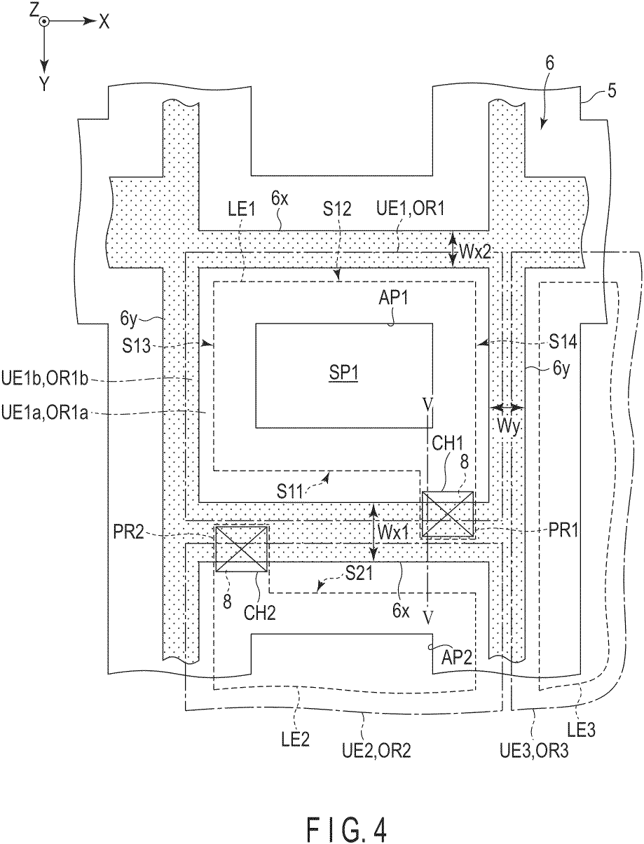

FIG. 4 is a schematic plan view in which the vicinity of subpixel SP1 in FIG. 2 is enlarged. Of the area surrounded by the chain lines showing the outer shapes of the upper electrode UE1 and the organic layer OR1, the portion overlapping the partition 6 corresponds to the second upper electrode UE1b and second organic layer OR1b described above. Further, of the area surrounded by the chain lines, the portion located inside the second upper electrode UE1b and the second organic layer OR1b corresponds to the first upper electrode UE1a and first organic layer OR1a described above.

The second upper electrode UE1b and the second organic layer OR1b surround the first upper electrode UE1a, the first organic layer OR1a and the aperture AP1. Similarly, the second upper electrode UE2b and second organic layer oR2b shown in FIG. 3 surround the first upper electrode UE2a, the first organic layer oR2a and the aperture AP2. The second upper electrode UE3b and second organic layer OR3b shown in FIG. 3 surround the first upper electrode UE3a, the first organic layer OR3a and the aperture AP3.

A filling material 8 is provided in the contact holes CH1 and CH2 as explained in detail later with reference to FIG. 5. The first partition 6x located between the apertures AP1 and AP2 overlaps part of the contact hole CH1 and part of the filling material 8. Further, the rib 5 overlaps the entire contact hole CH1 and the entire filling material 8. The first partition 6x may overlap the entire contact hole CH1 and the entire filling material 8. In the example of FIG. 4, the contact hole CH1 also overlaps the first organic layer OR1a, the second organic layer OR1b, the first upper electrode UE1a and the second upper electrode UE1b.

The first partition 6x overlapping the contact hole CH1 has width Wx1 in the second direction Y. The first partition 6x which does not overlap the contact hole CH1 (the first partition 6x in the upper part of the figure) has width Wx2. Each second partition 6y has width Wy in the first direction X. In the example of FIG. 4, width Wx1 is greater than width Wx2 and width Wy (Wx1 > Wx2, Wy). For example, width Wy is equal to width Wx2.

The lower electrode LE1 comprises first and second sides S11 and S12 parallel to the first direction X, and third and fourth sides S13 and S14 parallel to the second direction Y. In the example of FIG. 4, none of the sides S11, S12, S13 and S14 overlaps the partition 6. The first side S11 is located between the contact hole CH1 and the aperture AP1 in the second direction Y. The protrusion PR1 protrudes from the first side S11 toward the lower electrode LE2 and overlaps the contact hole CH1.

The first partition 6x which overlaps part of the contact hole CH1 also overlaps part of the contact hole CH2. The contact holes CH1 and CH2 are arranged in the first direction X. The lower electrode LE2 comprises a first side S21 near this first partition 6x. None of the first side S21 and the other sides of the lower electrode LE2 overlaps the partition 6 in the same manner as the sides S12, S13 and S14 of the lower electrode LE1. The protrusion PR2 protrudes from the first side S21 toward the lower electrode LE1 and overlaps the contact hole CH2. Although not shown in FIG. 4, regarding the lower electrode LE3, the side close to the contact hole CH3 overlaps the first partition 6x, and a large part of the other sides does not overlap the partition 6 (see FIG. 2).

The rib 5 overlaps the entire contact hole CH2 and the entire filling material 8 provided in the contact hole CH2. Part of the contact hole CH2 overlaps the organic layer OR2 and the upper electrode UE2. In the example of FIG. 4, the contact hole CH1 does not overlap the organic layer OR2 or the upper electrode UE2. The contact hole CH2 does not overlap the organic layer OR1 or the upper electrode UE1.

FIG. 5 is a schematic cross-sectional view of the display device DSP along the V-V line of FIG. 4. In this figure, the substrate 10, resinous layers 13 and 15 and sealing layer 14 shown in FIG. 3 are omitted.

The contact hole CH1 penetrates the insulating layer 12. The protrusion PR1 of the lower electrode LE1 is in contact with a conductive layer CL included in the circuit layer 11 through the contact hole CH1. The conductive layer CL is equivalent to, for example, the source electrode or drain electrode of the driver transistor 3 shown in FIG. 1.

The filling material 8 is provided inside the contact hole CH1. The filling material 8 may be formed of, for example, an insulating organic material such as polyimide. The filling material 8 may be formed of the same material as the insulating layer 12. The thickness of the filling material 8 is greater than that of the rib 5.

The filling material 8 covers, of the lower electrode LE1, the portion depressed by the contact hole CH1 (part of the protrusion PR1). In the example of FIG. 5, the upper surface 8a of the filling material 8 is substantially coincident with, of the lower electrode LE1, the upper surface of the portion located around the contact hole CH1. It should be noted that the upper surface 8a may slightly protrude from, of the lower electrode LE1, the upper surface of the portion located around the contact hole CH1, or may be located slightly under this upper surface.

In the present embodiment, the upper surface 8a is covered with the rib 5. In other words, at least part of the filling material 8 is located between the lower electrode LE1 and the rib 5 in a third direction Z (the thickness direction of the insulating layer 12 and the rib 5).

The lower portion 61 of the first partition 6x (partition 6) comprises side surfaces 61a and 61b. The first upper electrode UE1a is in contact with part of the side surface 61a. The other portion of the side surface 61a is covered with the sealing layer 71. Similarly, the first upper electrode UE2a is in contact with part of the side surface 61b. The other portion of the side surface 61b is covered with the sealing layer 72.

The upper portion 62 of the first partition 6x comprises an end portion 62a protruding from the side surface 61a and an end portion 62b protruding from the side surface 61b. In the example of FIG. 5, the sealing layer 71 covers the lower surface of the end portion 62a, and the sealing layer 72 covers the lower surface of the end portion 62b.

The second organic layers OR1b and OR2b located on the first partition 6x are spaced apart from each other in the second direction Y. The second upper electrodes UE1b and UE2b located above the first partition 6x are spaced apart from each other in the second direction Y. Further, the end portion 71a of the sealing layer 71 and the end portion 72a of the sealing layer 72 are located on the first partition 6x and are spaced apart from each other in the second direction Y.

In the example of FIG. 5, the side surface 61a is located above the contact hole CH1 and the filling material 8. Although not shown in the section of FIG. 5, the side surface 61b is located above the contact hole CH2. In other words, the side surface 61a overlaps the contact hole CH1 as seen in plan view, and the side surface 61b overlaps the contact hole CH2 as seen in plan view.

The cross-sectional structure near the contact holes CH2 and CH3 are similar to the cross-sectional structure near the contact hole CH1 in FIG. 5. In other words, a filling material 8 which covers the lower electrode LE2 is provided inside the contact hole CH2. The upper surface 8a of the filling material 8 is covered with the rib 5. A filling material 8 which covers the lower electrode LE3 is provided inside the contact hole CH3. The upper surface 8a of the filling material 8 is covered with the rib 5.

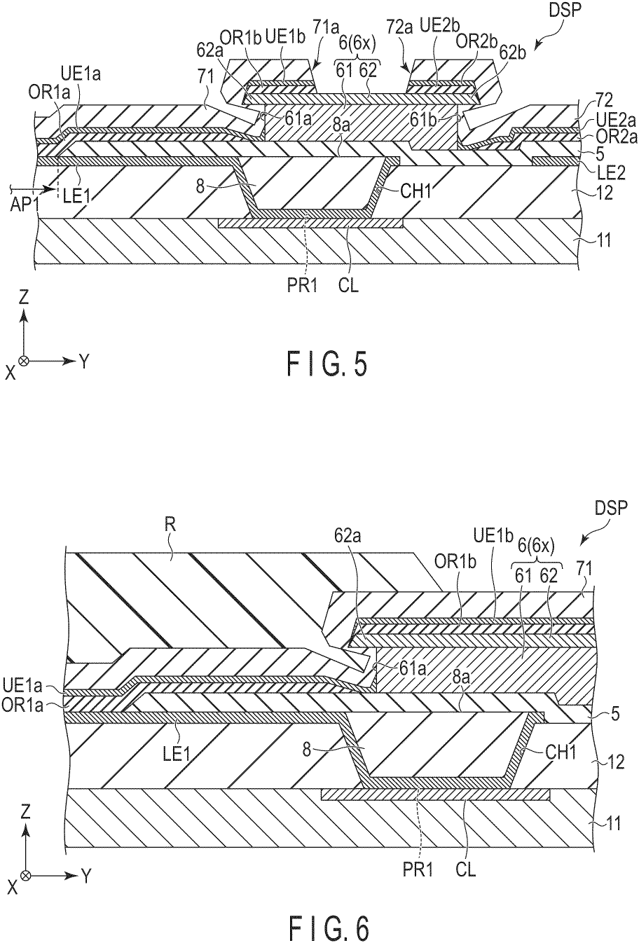

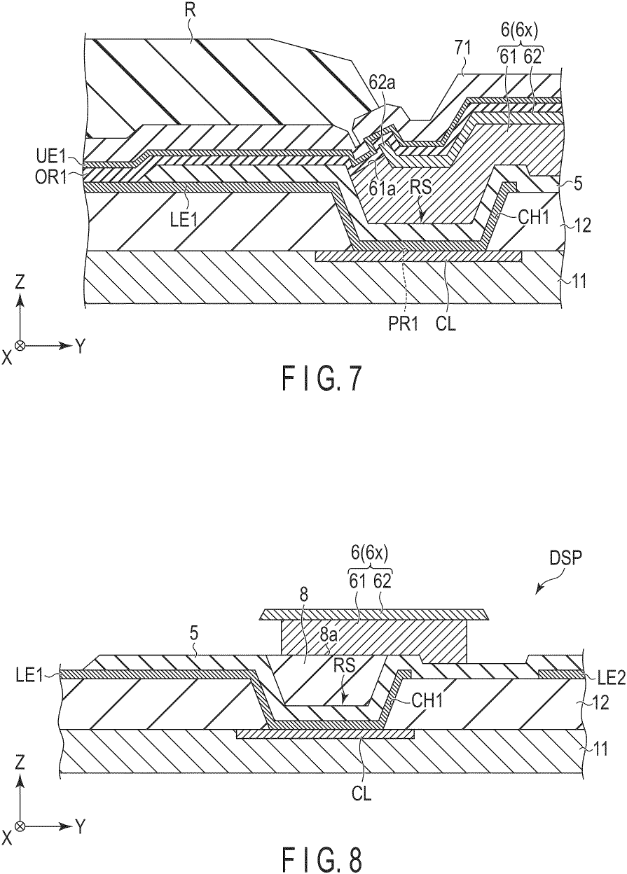

Now, this specification explains examples of effects obtained by the present embodiment with reference to FIG. 6 and FIG. 7.

FIG. 6 is a schematic cross-sectional view showing part of the manufacturing process of the display device DSP. To form the organic layer OR1, first, the base material is deposited in the entire display area DA. At this time, the material is divided into the first organic layer OR1a and the second organic layer OR1b by the partition 6. Subsequently, the base material of the upper electrode UE1 is deposited in the entire display area DA. At this time, the material is divided into the first upper electrode UE1a and the second upper electrode UE1b by the partition 6.

Further, the sealing layer 71 is formed on the first upper electrode UE1a and the second upper electrode UE1b. Ultimately, a resist R is formed on the sealing layer 71 in the area in which the first organic layer OR1a, the second organic layer OR1b, the first upper electrode UE1a and the second upper electrode UE1b should remain. Subsequently, of the first organic layer OR1a, the second organic layer OR1b, the first upper electrode UE1a, the second upper electrode UE1b and the sealing layer 71, the portion which is not covered with the resist R is removed by etching.

FIG. 7 is a schematic cross-sectional view of a display device according to a comparative example and shows a manufacturing process similar to that of FIG. 6. In this comparative example, the filling material 8 is not provided in the contact hole CH1. As the rib 5 formed of an inorganic material is sufficiently thinner than the insulating layer 12 formed of an organic material, the rib 5 is depressed above the contact hole CH1, and a recess RS is formed. Further, the side surface 61a of the lower portion 61 is located inside the recess RS.

In the structure of the comparative example, the end portion 62a of the upper portion 62 faces the upper side compared to the structure of FIG. 6. Thus, there is a possibility that the first partition 6x does not divide the organic layer OR1 or the upper electrode UE1. In this case, when the resist R is formed, and etching is conducted, the end portion of the organic layer OR1 constituting the display element is exposed from the upper electrode UE1 and the sealing layer 71. In general, the resistance of the organic layer OR1 to moisture is low. Thus, if moisture enters the organic layer OR1 through the exposed end portion, a display failure may occur.

In the present embodiment, the filling material 8 is provided inside the contact hole CH1. Therefore, the formation of the recess RS is prevented. Thus, the first partition 6x having a good shape is formed near the contact hole CH1. In this way, the organic layer OR1 can be divided into the first organic layer OR1a and the second organic layer OR1b. In this case, the end portion of the first organic layer OR1a is satisfactorily covered with the first upper electrode UE1a and the sealing layer 71, thereby preventing moisture from entering the first organic layer OR1a. As a result, a display failure is prevented. The display quality of the display device DSP is improved.

In FIG. 5 and FIG. 6, the effects of the present embodiment are explained, focusing attention on the organic layer OR1. However, similar effects can be obtained regarding the organic layers OR2 and OR3 as the filling material 8 is provided inside the contact holes CH2 and CH3.

In the present embodiment, the filling material 8 is provided between the lower electrodes LE1, LE2 and LE3 and the rib 5. Therefore, none of the organic layers OR1, OR2 and OR3 is in contact with the filling material 8. In this case, even if moisture is contained in the filling material 8, it is possible to prevent the moisture from reaching the organic layers OR1, OR2 and OR3.

In the present embodiment, the lower electrodes LE1 and LE2 comprise the protrusions PR1 and PR2. In this case, as shown in FIG. 2 and FIG. 4, the contact holes CH1 and CH2 can be arranged in the first direction X. This configuration can promote the efficiency of the layout of pixels PX.

Hereinafter, this specification discloses the second to fourth embodiments of the display device DSP. In these embodiments, this specification mainly looks at differences from the first embodiment. The explanation of the same structures as the first embodiment is omitted.

### [Second Embodiment]

FIG. 8 is a schematic cross-sectional view of a display device DSP according to the second embodiment. In this figure, a circuit layer 11, an insulating layer 12, a partition 6 (first partition 6x), a rib 5 and lower electrodes LE1 and LE2 are shown, and the other elements are omitted.

In the example of FIG. 8, the rib 5 covers the lower electrode LE1 inside a contact hole CH1. By this configuration, the rib 5 is depressed above the contact hole CH1, and a recess RS is formed. The recess RS is filled with a filling material 8. At least part of the upper surface 8a of the filling material 8 is covered with a lower portion 61.

In this way, in the example of FIG. 8, at least part of the filling material 8 is located between the rib 5 and the partition 6 in a third direction Z. Even in this case, the first partition 6x having a good shape is formed near the contact hole CH1. Thus, effects similar to those of the first embodiment can be obtained.

For example, when the display device DSP comprising the structure disclosed in FIG. 5 in the first embodiment is manufactured, it is necessary to form the filling material 8 before the process of forming the rib 5 after the process of forming the lower electrode LE1. In this case, compared to a case where the filling material 8 is not provided, the time for exposing the end portion of the lower electrode LE1 to the atmosphere is elongated. When the time for exposing the end portion of the lower electrode LE1 is long, there is a possibility that the lower electrode LE1 is degraded through the end portion.

When the display device DSP comprising the structure of FIG. 8 is manufactured, the rib 5 can be formed immediately after the process of forming the lower electrode LE1. Thus, the time for exposing the end portion of the lower electrode LE1 can be shortened. Thus, the degradation of the lower electrode LE1 can be prevented.

A structure similar to that of FIG. 8 can be also applied to the vicinity of contact holes CH2 and CH3. In this way, each of the effects described above can be also obtained in the vicinity of the contact holes CH2 and CH3.

### [Third Embodiment]

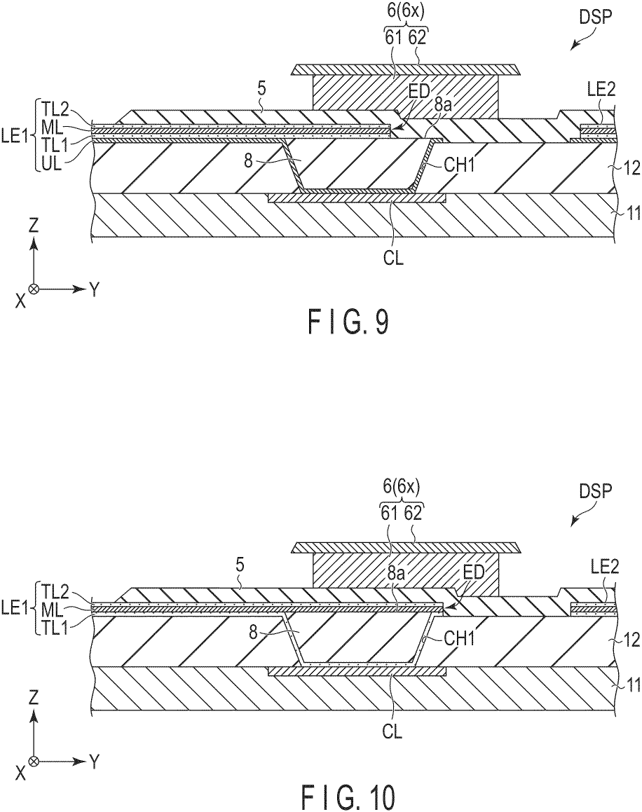

FIG. 9 is a schematic cross-sectional view of a display device DSP according to the third embodiment. In this figure, a circuit layer 11, an insulating layer 12, a partition 6 (first partition 6x), a rib 5 and lower electrodes LE1 and LE2 are shown, and the other elements are omitted.

In the example of FIG. 9, the lower electrode LE1 includes a first transparent conductive layer TL1, a metal layer ML, a second transparent conductive layer TL2 and an underlayer UL. All of these layers are conductive. The lower electrodes LE2 and LE3 comprise a structure similar to that of the lower electrode LE1.

The first transparent conductive layer TL1 and the second transparent conductive layer TL2 are formed of, for example, a transparent conductive material such as ITO. The metal layer ML is formed of, for example, a metal material excellent in reflectiveness such as silver. The underlayer UL may be formed of a transparent conductive material or may be formed of a metal material.

The underlayer UL covers the insulating layer 12 and is in contact with a conductive layer CL through a contact hole CH1. A filling material 8 covers, of the underlayer UL, the portion located inside the contact hole CH1. The first transparent conductive layer TL1 covers the underlayer UL and the upper surface 8a of the filling material 8. The metal layer ML covers the first transparent conductive layer TL1. The second transparent conductive layer TL2 covers the metal layer ML.

Thus, in the example of FIG. 9, at least part of the filling material 8 is located between the underlayer UL and the first transparent conductive layer TL1 in a third direction Z. Even in this case, the first partition 6x having a good shape is formed near the contact hole CH1. Thus, effects similar to those of the first embodiment can be obtained.

When the display device DSP comprising the structure of FIG. 9 is manufactured, the rib 5 can be formed immediately after the process of forming the first transparent conductive layer TL1, the metal layer ML and the second transparent conductive layer TL2. By this configuration, the time for exposing the end portion ED of the first transparent conductive layer TL1, the metal layer ML and the second transparent conductive layer TL2 can be shortened. Thus, the degradation of these layers can be prevented.

In the example of FIG. 9, the end portion ED of the first transparent conductive layer TL1, the metal layer ML and the second transparent conductive layer TL2 is located on the upper surface 8a. In other words, part of the upper surface 8a is not covered with the first transparent conductive layer TL1. As another example, the end portion ED may be covered with the first transparent conductive layer TL1 as a whole.

A structure similar to that of FIG. 9 can be also applied to the vicinity of contact holes CH2 and CH3. In this way, each of the effects described above can be also obtained in the vicinity of the contact holes CH2 and CH3.

### [Fourth Embodiment]

FIG. 10 is a schematic cross-sectional view of a display device DSP according to the fourth embodiment. In this figure, a circuit layer 11, an insulating layer 12, a partition 6 (first partition 6x), a rib 5 and lower electrodes LE1 and LE2 are shown, and the other elements are omitted.

In the example of FIG. 10, the lower electrode LE1 includes a first transparent conductive layer TL1, a metal layer ML and a second transparent conductive layer TL2. All of these layers are conductive and can be formed of the materials exemplarily shown in the third embodiment. The lower electrodes LE2 and LE3 comprise a structure similar to that of the lower electrode LE1.

In the example of FIG. 10, the first transparent conductive layer TL1 covers the insulating layer 12 and is in contact with a conductive layer CL through a contact hole CH1. A filling material 8 covers, of the first transparent conductive layer TL1, the portion located inside the contact hole CH1. The metal layer ML covers the first transparent conductive layer TL1 and the upper surface 8a of the filling material 8. The second transparent conductive layer TL2 covers the metal layer ML.

Thus, in the example of FIG. 10, the filling material 8 is located between the first transparent conductive layer TL1 and the metal layer ML in a third direction Z. Even in this case, the first partition 6x having a good shape is formed near the contact hole CH1. Thus, effects similar to those of the first embodiment can be obtained.

In the example of FIG. 10, the end portion ED of the first transparent conductive layer TL1, the metal layer ML and the second transparent conductive layer TL2 is located outside the contact hole CH1. Thus, the entire filling material 8 is surrounded by the first transparent conductive layer TL1 and the metal layer ML. As another example, the end portion of the first transparent conductive layer TL1 may be covered with the filling material 8. The end portion of the metal layer ML and the second transparent conductive layer TL2 may be located on the upper surface 8a.

A structure similar to that of FIG. 10 can be also applied to the vicinity of contact holes CH2 and CH3. In this way, each of the effects described above can be also obtained in the vicinity of the contact holes CH2 and CH3.

All of the display devices that can be implemented by a person of ordinary skill in the art through arbitrary design changes to the display device described above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each of the above embodiments and are self-explanatory from the descriptions of the specification or can be arbitrarily conceived by a person of ordinary skill in the art are considered as the effects of the present invention as a matter of course.

What is claimed is:

1. A display device comprising:
a substrate;
a pixel circuit provided above the substrate;
an insulating layer which covers the pixel circuit and comprises a contact hole;
a lower electrode provided above the insulating layer and connected to the pixel circuit through the contact hole;
an upper electrode facing the lower electrode;
an organic layer which is located between the lower electrode and the upper electrode and emits light based on a potential difference between the lower electrode and the upper electrode;
a rib formed of an inorganic material and comprising an aperture overlapping the lower electrode;
a partition provided above the rib; and
a filling material provided inside the contact hole, wherein
the organic layer includes a first organic layer which is in contact with the lower electrode through the aperture, and a second organic layer located on the partition and spaced apart from the first organic layer, and
the partition and the rib overlap at least part of the contact hole and the filling material as seen in plan view.

2. The display device of claim 1, wherein
at least part of the filling material is located between the lower electrode and the rib in a thickness direction of the insulating layer.

3. The display device of claim 1, wherein
at least part of the filling material is located between the rib and the partition in a thickness direction of the insulating layer.

4. The display device of claim 1, wherein
the lower electrode includes:
a conductive underlayer which covers the insulating layer;
a first transparent conductive layer which is formed of a transparent conductive material and covers the underlayer;
a metal layer which is formed of a metal material and covers the first transparent conductive layer; and
a second transparent conductive layer which is formed of a transparent conductive material and covers the metal layer,
the underlayer is connected to the pixel circuit through the contact hole, and
at least part of the filling material is located between the underlayer and the first transparent conductive layer.

5. The display device of claim 1, wherein
the lower electrode includes:
a first transparent conductive layer which is formed of a transparent conductive material and covers the insulating layer;
a metal layer which is formed of a metal material and covers the first transparent conductive layer; and
a second transparent conductive layer which is formed of a transparent conductive material and covers the metal layer,
the first transparent conductive layer is connected to the pixel circuit through the contact hole, and
at least part of the filling material is located between the first transparent conductive layer and the metal layer.

6. The display device of claim 1, wherein
the partition includes a lower portion provided on the rib, and an upper portion provided on the lower portion and comprising an end portion protruding from a side surface of the lower portion, and
the second organic layer is provided on the upper portion.

7. The display device of claim 6, wherein
the side surface of the lower portion overlaps the contact hole as seen in plan view.

8. The display device of claim 6, wherein
the upper electrode includes a first upper electrode covering the first organic layer, and a second upper electrode covering the second organic layer and spaced apart from the first upper electrode, and
the first upper electrode is in contact with the side surface.

9. The display device of claim 8, wherein
the lower portion is conductive.

10. The display device of claim 8, further comprising a sealing layer formed of an inorganic material and covering the first upper electrode, the side surface and the second upper electrode.

11. The display device of claim 1, wherein
the lower electrode comprises a first side located between the contact hole and the aperture as seen in plan view, and a protrusion protruding from the first side and overlapping the contact hole as seen in plan view.

12. The display device of claim 1, wherein
the partition surrounds the aperture as seen in plan view.

13. The display device of claim 1, wherein
the second organic layer surrounds the aperture as seen in plan view.

14. The display device of claim 1, wherein
the second organic layer overlaps the contact hole as seen in plan view.

15. The display device of claim 1, wherein
a thickness of the rib is less than a thickness of the partition.

16. The display device of claim 1, comprising first, second and third subpixels each including the pixel circuit, the contact hole, the lower electrode, the upper electrode, the organic layer and the aperture, wherein
the first subpixel and the third subpixel are arranged in a first direction,
the first subpixel and the second subpixel are arranged in a second direction intersecting with the first direction, and
the partition comprises a first partition provided between the aperture of the first subpixel and the aperture of the second subpixel, and a second partition provided between the aperture of the first subpixel and the aperture of the third subpixel.

17. The display device of claim 16, wherein
a width of the first partition in the second direction is greater than a width of the second partition in the first direction.

18. The display device of claim 16, wherein
the contact hole of the first subpixel overlaps the first partition as seen in plan view.

19. The display device of claim 18, wherein
the contact hole of the second subpixel overlaps the first partition as seen in plan view, and is adjacent to the contact hole of the first subpixel in the first direction.

20. The display device of claim 16, wherein
the second organic layer of the first subpixel and the second organic layer of the second subpixel are located on the first partition and are spaced apart from each other in the second direction.
